(19) United States
(12) Patent Application Publication
(10) Pub. No.: US 2014/0111925 A1
(43) Pub. Date: Apr. 24, 2014

(54) ELECTRONIC DEVICE

(71) Applicant: COMPAL ELECTRONICS, INC., Taipei City (TW)

(72) Inventors: Chia-Yuan CHANG, TAIPEI (TW); Chong-Kuo LAI, TAIPEI (TW); Mao-Wei LEE, TAIPEI (TW)

(73) Assignee: COMPAL ELECTRONICS, INC., Taipei City (TW)

(21) Appl. No.: 13/705,172

(22) Filed: Dec. 5, 2012

(30) Foreign Application Priority Data
Oct. 23, 2012 (TW) 101139105

(51) Int. Cl. H05K 5/02

(52) U.S. Cl. CPC H05K 5/0226
USPC 361/679.09; 361/679.01

(57) ABSTRACT

An electronic device includes a first housing, a second housing and a connection member. The second housing is pivotally connected with the first housing and rotated relative to the first housing in a close position or in an open position. The connection member is interconnected between the first housing and the second housing, and the connection member includes a bendable portion. When the second housing is in the close position relative to the first housing, the connection member is in contact with the first housing and the second housing. When the second housing is in the open position relative to the first housing, the bendable portion of the connection member is bent to be apart from the first housing and the second housing.

### RELATED APPLICATIONS

The present application is based on, and claims priority from, Taiwan Application Serial Number 101139105, filed on Oct. 23, 2012, the disclosure of which is hereby incorporated by reference herein in its entirety.

### BACKGROUND

1. Field of Invention

The present invention relates to a portable electronic device. More particularly, the present invention relates to a notebook computer.

2. Description of Related Art

The current notebook computer devices all have a host portion and a display portion, and the host portion has a few footpads at its bottom surface. The first function of the footpad is to provide “non-slipping” function so that the host portion cannot slide on a support surface (such as a desktop) to be conveniently operated by a user. The second function of the footpad is to elevate the underside of the host portion such that, on the one hand, the underside of the host portion obtains ventilation space conducive to heat dissipation, on the other hand, the keyboard is thus inclined to facilitate comfortable typing.

However, the current trend of the notebook computer design is a portable slim design, such that the thickness of the footpad will undoubtedly affect the thickness of the notebook computer, and thus not conducive to carry. Moreover, a thick footpad is not attractive in appearance. The footpad design seems to have caused an obstacle on the reduction of the thickness of the notebook computer.

In view of the above problems, there is an urgent need of the innovative design for the footpad of the notebook computer on the current market.

### SUMMARY

It is therefore an objective of the present invention to provide an electronic device to deal with the above-discussed problems.

In accordance with the foregoing and other objectives of the present invention, an electronic device includes a first housing, a second housing and a connection member. The second housing is pivotally connected with the first housing and rotated relative to the first housing in a close position or in an open position. The connection member is interconnected between the first housing and the second housing, and the connection member includes a bendable portion. When the second housing is in the close position relative to the first housing, the connection member is in contact with the first housing and the second housing. When the second housing is in the open position relative to the first housing, the bendable portion of the connection member is bent to be apart from the first housing and the second housing.

According to an embodiment disclosed herein, the first housing has a keyboard while the second housing has a display screen.

According to an embodiment disclosed herein, the second housing has a pivot member, the connection member is in contact with a bottom surface of the first housing and the pivot member when the second housing is in the close position relative to the first housing.

According to an embodiment disclosed herein, the connection member includes a first hard part, a second hard part, a third hard part and a fourth hard part which are sequentially connected, the fourth hard part is fastened to the bottom surface of the first housing, the first hard part is fastened to the pivot member, the second hard part and the third hard part are contained within the bendable portion of the connection member.

According to an embodiment disclosed herein, the first, second, third and fourth hard parts are connected by bendable materials.

According to an embodiment disclosed herein, a first bendable joint, which are interconnected between the second and third hard parts, has a first cutout, and the first cutout faces towards the first housing.

According to an embodiment disclosed herein, a second bendable joint, which are interconnected between the first and second hard parts, has a second cutout, a third bendable joint, which are interconnected between the third and fourth hard parts, has a third cutout, the second and third cutouts face opposite to the first cutout.

According to an embodiment disclosed herein, the first, second and third cutouts have respective two inner sidewalls in contact with each other when the second housing is in the open position relative to the first housing.

According to an embodiment disclosed herein, the connection member is made from a soft rubber material enclosing the first, second, third and fourth hard parts to form the first, second and third bendable joints.

According to an embodiment disclosed herein, the connection member is made by a double injection molding made of a soft rubber material and a hard material.

According to an embodiment disclosed herein, the bendable portion of the connection member supports the electronic device when the bendable portion is bent to be apart from the first housing and the second housing.

Thus, the electronic device is equipped with the bendable connection member, which can be bent to provide a support force for the electronic device. When the second housing is in the close position relative to the first housing, the bendable connection member is in contact with the first housing and the second housing, thereby reducing a thickness and volume of the electronic device to a smaller size for easy carrying and storage.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a side view of an electronic device according to one embodiment of this invention;

FIG. 2 illustrates the electronic device in FIG. 1 with its two housings opened;

FIG. 3 illustrates a cross-sectional view of a pivot portion of the electronic device in FIG. 1;

FIG. 4 illustrates a cross-sectional view of the pivot portion of the electronic device in FIG. 3 with its two housings opened;

FIG. 5 illustrates a cross-sectional view of a connection member of an electronic device according to one embodiment of this invention;

FIG. 6 illustrates a cross-sectional view of the connection member of the electronic device in FIG. 5 with its two housings opened;

FIG. 7 illustrates a cross-sectional view of a connection member according to another embodiment of this invention;

FIG. 8 illustrates a cross-sectional view of the bent connection member in FIG. 7; and

FIG. 9 illustrates a connection member of an electronic device with its two housings opened according to still another embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

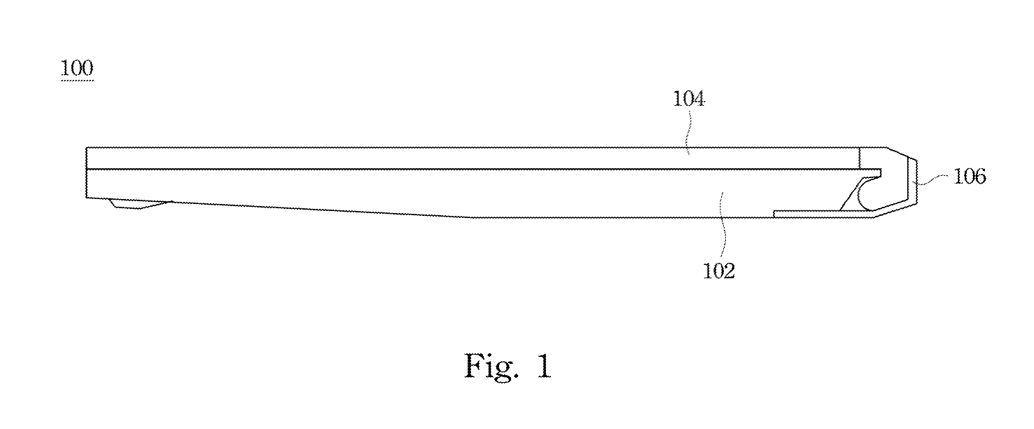

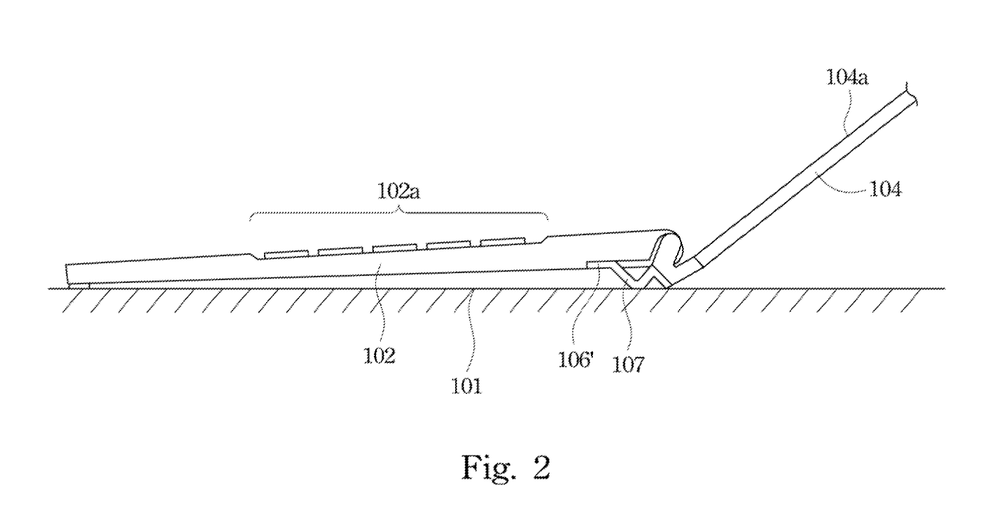

FIG. 1 illustrates a side view of an electronic device according to one embodiment of this invention, and FIG. 2 illustrates the electronic device in FIG. 1 with its two housings opened. An electronic device 100 includes a first housing 102 and a second housing 104. An edge of the second housing 104 is pivotally connected with an edge of the first housing 102 such that the second housing 104 can be rotated relative to the first housing 102 in a close position (as illustrated in FIG. 1) or in an open position (as illustrated in FIG. 2). The electronic device 100 can be a notebook computer or other foldable electronic device. The first housing 102 can be a host part of the notebook computer, which contains a main board, a processor and other electronic components inside, and the first housing 102 is also equipped with a keyboard 102a for inputting information. The second housing 104 can be a display portion of the notebook computer and thus equipped with a display screen 104a. When the second housing 104 is in the close position relative to the first housing 102, the electronic device 100 is easily portable and convenient for storage. When the second housing 104 is in the open position relative to first housing 102, the keyboard 102a on the first housing 102 can be available for inputting information while the display screen 104a of the second housing 104 can be exposed to display visual information.

A bendable connection member 106 is interconnected between the first housing 102 and the second housing 104. When the second housing 104 is in the close position relative to the first housing 102 (as illustrated in FIG. 1), the connection member 106 is in contact with a pivot portion of the first housing 102 and the second housing 104, thereby reducing a thickness and volume of the electronic device 100 to a smaller size for easy carrying and storage. When the second housing 104 is in the open position relative to the first housing 102 (as illustrated in FIG. 2), the electronic device 100 is ready for performing its functions. In the mean time, a bendable portion 107 of the connection member 106 is thus bent to be apart from the first housing 102 and the second housing 104, and the bendable portion 107 provides a support force for the electronic device 100. In this embodiment, the connection member 106′ performs the same function as a footpad does, e.g., to raise an edge of the first housing 102 above a support surface 101 (such as a desk surface), thereby providing a heat dissipation space for a bottom surface of the first housing 102 and providing an inclined keyboard 102a on the first housing 102 to facilitate typing.

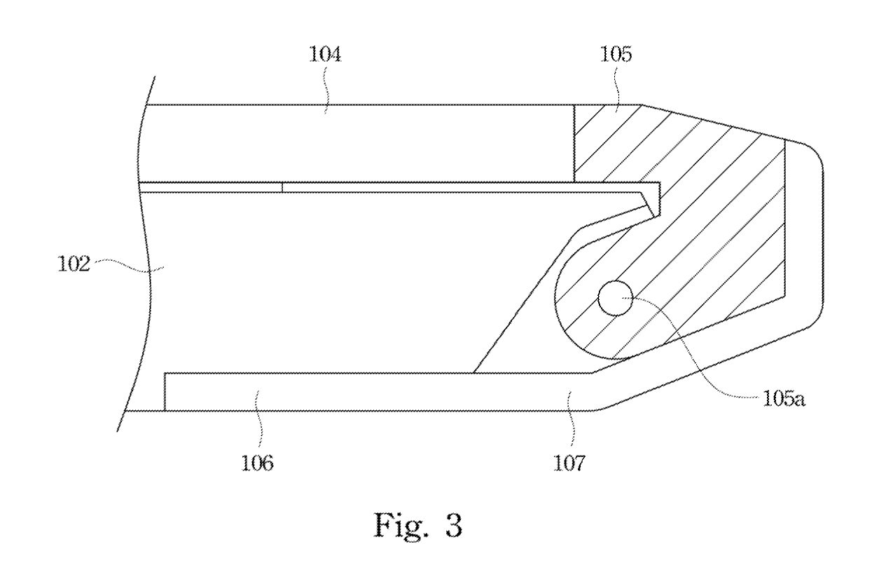

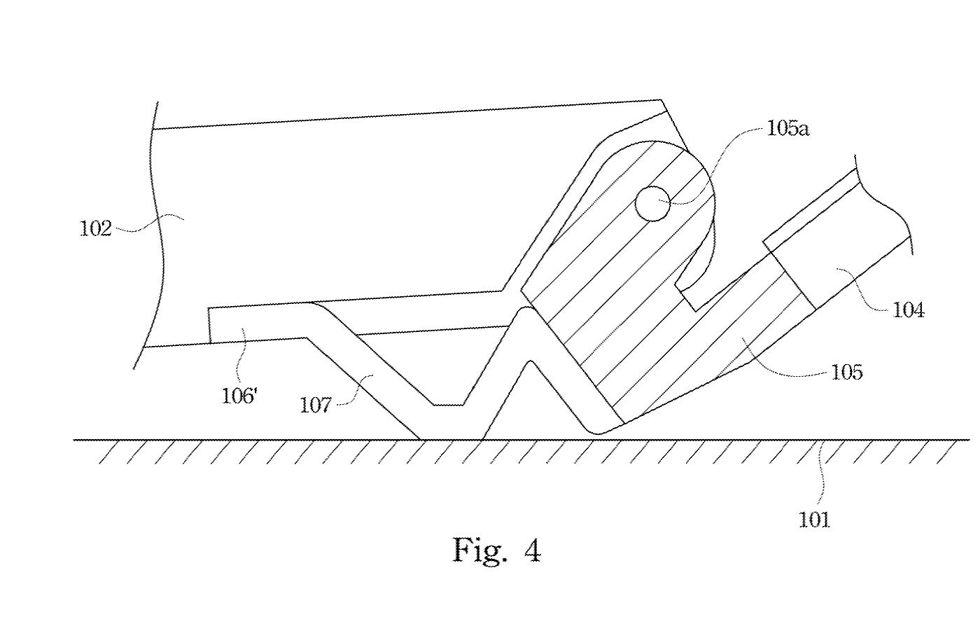

FIG. 3 illustrates a cross-sectional view of a pivot portion of the electronic device in FIG. 1, and FIG. 4 illustrates a cross-sectional view of the pivot portion of the electronic device in FIG. 3 with its two housings opened. The second housing 104 is rotatably connected with the first housing 102 by a pivot member 105. The pivot member 105 is pivotally connected with the first housing 102 by a rotation shaft 105a. When the second housing 104 is in a close position relative to the first housing 102 (as illustrated in FIG. 3), the connection member 106 is in contact with a bottom surface of the first housing 102 and the pivot member 105, thereby reducing a thickness and volume of the electronic device 100 to a smaller size for easy carrying and storage. When the second housing 104 is in the open position relative to the first housing 102 (as illustrated in FIG. 4), the electronic device 100 is ready for performing its functions. Meantime, the bendable portion 107 of the connection member 106′ is thus bent to be apart from the bottom surface of the first housing 102 and the pivot member 105, thereby raising an edge of the first housing 102 above a support surface 101 (such as a desk surface) so as to perform the same function as the footpad does. In this embodiment, the pivot member 105 is equipped with a V-shaped cross-section, but not being limited to this cross-section, other shaped cross-sections (such as an L-shaped cross-section) may be applicable.

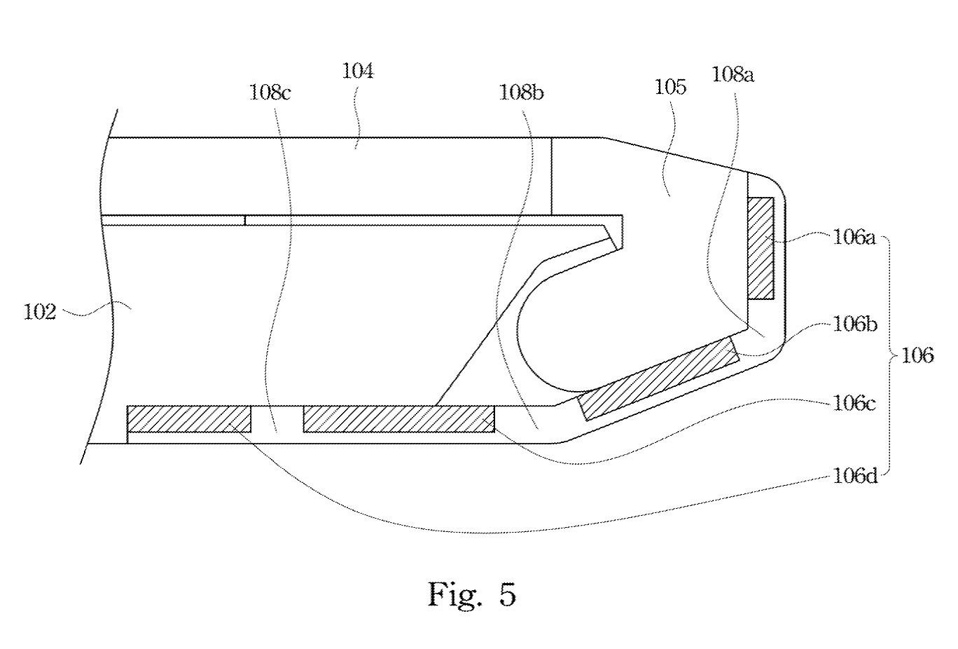

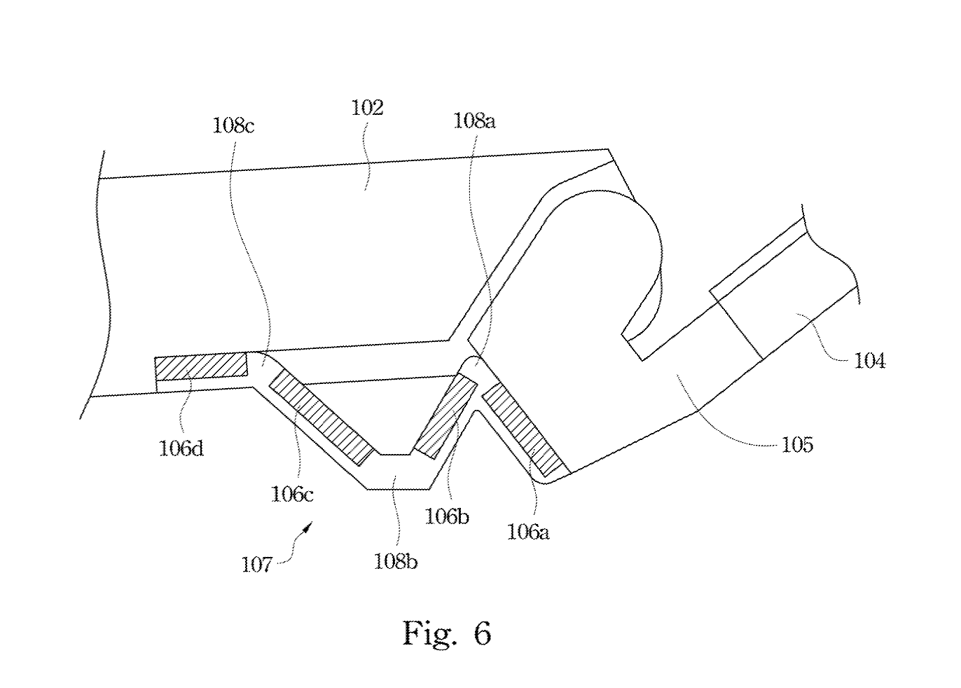

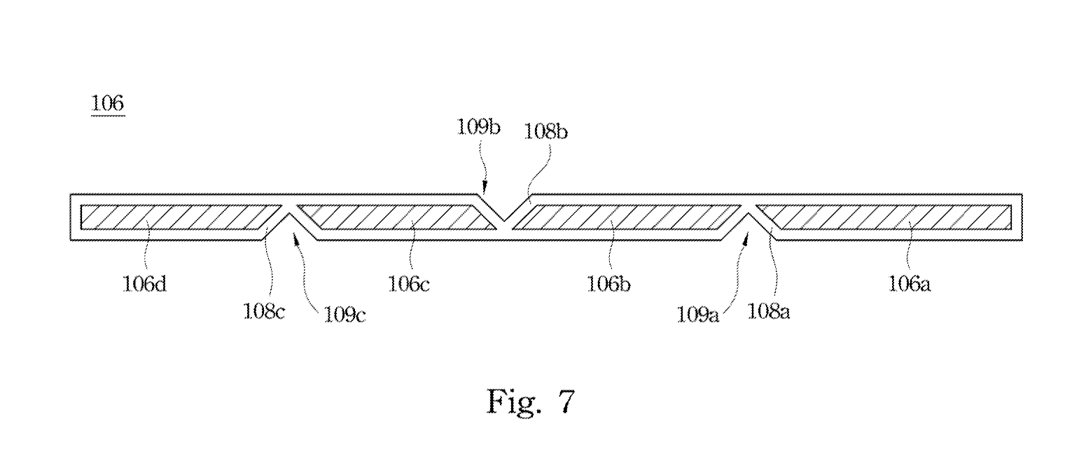

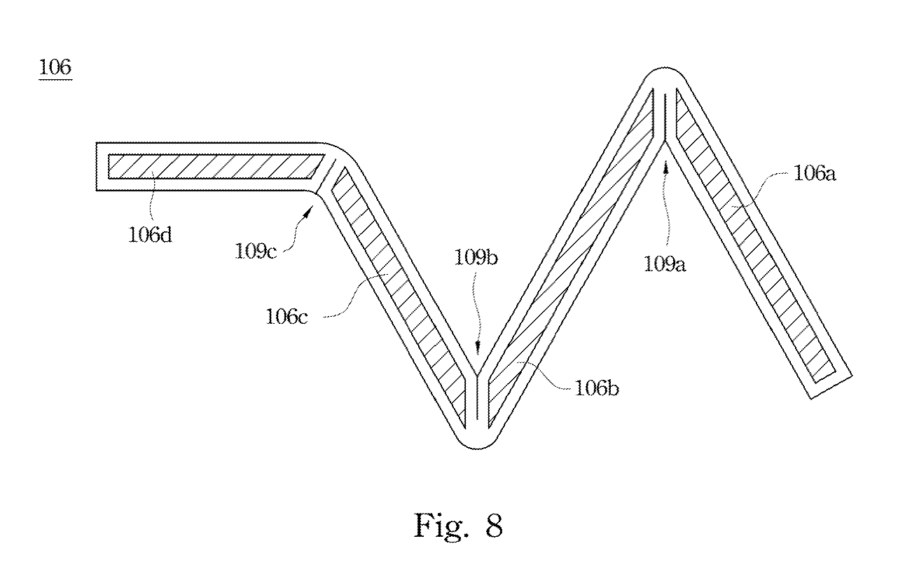

FIG. 5 illustrates a cross-sectional view of a connection member of an electronic device according to one embodiment of this invention, and FIG. 6 illustrates a cross-sectional view of the connection member of electronic device in FIG. 5 with its two housings opened. The connection member 106 includes a first hard part 106a, a second hard part 106b, a third hard part 106c and a fourth hard part 106d which are sequentially connected, the fourth hard part 106d is fastened to the bottom surface of the first housing 102, and the first hard part 106a is fastened to the pivot member 105. In addition, the second hard part 106b and the third hard part 106c are contained within the bendable portion 107 of the connection member 106. Each adjacent-two hard parts are coupled by bendable materials such that the bendable materials form the bendable joint of the connection member 106. The connection member 106 can be made by a double injection molding made of a soft rubber material and a hard material. In another embodiment, the hard parts and bendable materials (such as a soft rubber band) are separately manufactured, and then the hard parts are attached to the soft rubber band to form the connection member 106 by a heat melting. In this embodiment, the hard parts can be attached or embedded to an inner surface of the connection member 106 (as illustrated in FIG. 5 and FIG. 6) or are enclosed by the bendable materials (as illustrated in FIG. 7 and FIG. 8). In this embodiment, the soft rubber materials or other bendable materials provide a bendable feature for the connection member 106 as well as non-slip and seismic features.

FIG. 7 illustrates a cross-sectional view of a connection member according to another embodiment of this invention, and FIG. 8 illustrates a cross-sectional view of the bent connection member in FIG. 7. In order to precisely control a bendable joint of the connection member 106 to be a desired bending direction and angle, a cutout is designed at the bendable joint. In particular, a first bendable joint 108b, which are interconnected between the second hard part 106b and the third hard part 106c, has a first cutout 109b, and the first cutout 109b faces towards the first housing 102 (referring to FIG. 5 and FIG. 6). A second bendable joint 108a, which are interconnected between the first hard part 106a and the second hard part 106b, has a second cutout 109a while a third bendable joint 108c, which are interconnected between the third hard part 106c and fourth hard part 106d, has a third cutout 109c. The second cutout 109a and third cutouts 109c face opposite to the first cutout 109b. When forces are applied at two opposite ends of the connection member 106 (such as the circumstances illustrated in FIG. 8), bending actions occur at the first cutout 109b, the second cutout 109a and the third cutout 109c. When the connection member 106 is bent, i.e., the second housing 104 is in an open position relative to the first housing 102, the first cutout 109b, second cutout 109a and third cutout 109c have their respective two inner sidewalls in contact with each other to control a bending angle of each bendable joint. In this embodiment, the connection member 106 can be made from a soft rubber material to enclose the first, second, third and fourth hard parts (106a, 106b, 106c, 106d) so as to form the first, second and third bendable joints (108b, 108a, 108c).

However, the connection member 106 may be made from other bendable materials, e.g., bendable metals, and does not necessarily need the hard parts to serve as a support structure. In addition, the cutout at the bendable joint of the connection member 106 is not a necessary design, and the bendable joint without a cutout still performs the bending function.

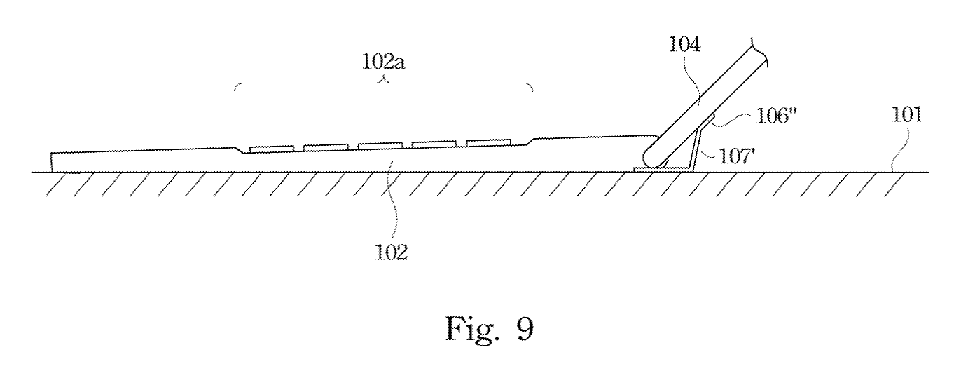

In addition the bendable portion of the connection member being bent to serve as a footpad to support the electronic device, the bendable portion may be located at other position of the connection member to support the display portion of the electronic device. FIG. 9 illustrates a connection member of an electronic device with its two housings opened according to still another embodiment of this invention. A connection member 106″ is interconnected between the first housing 102 and the second housing 104 (the display portion), the connection member 106″ is also equipped with a bendable portion 107′. When the second housing 104 is in the open position relative to the first housing 102, the bendable portion 107 of the connection member 106″ is bent to be apart from the first housing 102 and second housing 104 and serves as a support frame for the second housing 104.

According to the above-discussed embodiments, the electronic device is equipped with the bendable connection member, which can be bent to provide a support force for the electronic device. When the second housing is in the close position relative to the first housing, the bendable connection member is in contact with the first housing and the second housing, thereby reducing a thickness and volume of the electronic device to a smaller size for easy carrying and storage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device comprising:
a first housing;
a second housing being pivotally connected with the first housing and rotated relative to the first housing in a close position or in an open position; and
a connection member being interconnected between the first housing and the second housing, and the connection member comprises a bendable portion;
when the second housing is in the close position relative to the first housing, the connection member is in contact with the first housing and the second housing;
when the second housing is in the open position relative to the first housing, the bendable portion of the connection member is bent to be apart from the first housing and the second housing.

2. The electronic device of claim 1, wherein the first housing has a keyboard while the second housing has a display screen.

3. The electronic device of claim 1, wherein the second housing has a pivot member, the connection member is in contact with a bottom surface of the first housing and the pivot member when the second housing is in the close position relative to the first housing.

4. The electronic device of claim 3, wherein the connection member comprises a first hard part, a second hard part, a third hard part and a fourth hard part which are sequentially connected, the fourth hard part is fastened to the bottom surface of the first housing, the first hard part is fastened to the pivot member, the second hard part and the third hard part are contained within the bendable portion of the connection member.

5. The electronic device of claim 4, wherein the first, second, third and fourth hard parts are connected by bendable materials.

6. The electronic device of claim 5, wherein a first bendable joint, which are interconnected between the second and third hard parts, has a first cutout, and the first cutout faces towards the first housing.

7. The electronic device of claim 6, wherein a second bendable joint, which are interconnected between the first and second hard parts, has a second cutout, a third bendable joint, which are interconnected between the third and fourth hard parts, has a third cutout, the second and third cutouts face opposite to the first cutout.

8. The electronic device of claim 7, wherein the first, second and third cutouts have respective two inner sidewalls in contact with each other when the second housing is in the open position relative to the first housing.

9. The electronic device of claim 7, wherein the connection member is made from a soft rubber material enclosing the first, second, third and fourth hard parts to form the first, second and third bendable joints.

10. The electronic device of claim 1, wherein the connection member is made by a double injection molding made of a soft rubber material and a hard material.

11. The electronic device of claim 1, wherein the bendable portion of the connection member supports the electronic device when the bendable portion is bent to be apart from the first housing and the second housing.
